(19) United States
(12) Patent Application Publication
(10) Pub. No.: US 2011/0133613 A1
(43) Pub. Date: Jun. 9, 2011

(54) Payment terminal in two portions including an assembling device

(75) Inventors: Sebastien DESCAMPS, Dole (FR); Sylvain BRAUN, Routelle (FR)

(73) Assignee: PARKEON, Paris (FR)

(21) Appl. No.: 12/944,530

(22) Filed: Nov. 11, 2010

(30) Foreign Application Priority Data
Nov. 13, 2009 (FR) 09 58033

(51) Int. Cl. H05K 7/14

(52) U.S. Cl. 312/223.1

(57) ABSTRACT

The payment terminal includes a casing (4) containing an electronic payment apparatus, a supporting leg (7) of the casing (4) and a device (17) for assembling the casing (4) on the leg (7) said assembling device (17) includes a rod (39) firmly attached to a first module among the casing (4) and the leg (7) and a lock (53) borne by a second module among the casing (4) and the leg (7) and able to co-operate with the rod (39) for assembling the casing (4) and the leg (7). The assembling device (17) further includes elastic engagement means for elastically engaging the lock (53) onto the rod (39).

The present invention relates to a payment terminal including a casing containing an electronic payment apparatus, a supporting leg for supporting the casing and a device for assembling the casing on the leg, said assembling device includes a rod firmly attached to a first module among the casing and the leg, and a lock, borne by a second module among the casing and the leg and able to co-operate with the rod for the assembling of the casing and of the leg.

Certain payment terminals are designed in two portions and comprise a leg attached to the ground and a casing attached onto the leg, the sensitive elements of the terminal such as the chip card reader or the change selector being in the casing.

In order to assemble such payment terminals designed in two portions, the use of four threaded rods firmly attached to the leg and extending beyond the upper surface of the leg is known. In such devices, each threaded rod passes through the lower wall of the casing and is provided with a nut bearing against the lower inner surface of the casing. In order to perform the assembling, an operator has to open the door of the casing and screw the nuts onto the rods with suitable tools.

Known devices for assembling payment terminals therefore have the drawback of requiring the opening of the casing during their installation in the street. As the sensitive elements are contained in the casing, the risk of vandalism is thus increased upon mounting the payment terminal in the street, which often makes it mandatory to set into place a security perimeter around the installation area.

The risk of vandalism is all the greater since the time for mounting these devices is significant, notably because the operator has to separately screw each of the nuts on the associated screw, but also because due to the reduced dimensions of the casing, access to the nuts may require the removal of certain sub-assemblies of the casing.

An object of the present invention is therefore to propose a secured assembling device for assembling a payment terminal reducing the risk of vandalism, notably during the assembling.

For this purpose, the object of the present invention is therefore a payment terminal of the aforementioned type, characterized in that the assembling device further includes elastic engagement means for elastically engaging the lock on the rod.

According to other aspects of the invention, the payment terminal comprises one or more of the following features:

the rod includes a cam surface capable of co-operating with a cam-follower surface of the lock so as to cause stretching of the elastic engagement means,

the lock includes two jaws, delimiting between them the cam-follower surface and capable of sliding in opposite directions under the action of the rod,

the elastic engagement means include two springs capable of returning the jaws back towards each other so as to engage the lock on the rod,

the rod includes a cylindrical segment and a frusto-conical segment forming said cam surface and the cross-section of which gradually decreases upon moving away from the cylindrical segment,

the second module further includes a guide socket for guiding the rod,

the guide socket includes guide rails capable of guiding the lock translationally,

the rod includes a radial shoulder on which the lock is able to be supported upon its engagement on the rod,

the guide socket includes an upper surface, the lock includes a lower surface and the rod includes in the cylindrical segment, a flange forming a supporting abutment, capable of bearing upon the upper surface, the distance between the supporting abutment and the radial shoulder being substantially equal to the distance between the upper surface of the guiding socket and the lower surface of the lock,

the assembling device includes at least two rods firmly attached to the first module among the casing and the leg and at least the two locks, borne by the second module among the casing and the leg and each able to co-operate with an associated rod for assembling the casing and the leg and elastic engagement means for elastically engaging each lock onto the associated rod,

the second module further includes an unlocking plate capable of simultaneously disengaging all the locks from the associated rods,

the unlocking plate is capable of sliding relatively to the second module in a direction normal to the sliding direction of the jaws so as to generate a moving-apart of the jaws of each lock,

the second module includes a collecting hatch capable of blocking the sliding of the unlocking plate when the collecting hatch is closed,

the payment terminal further includes a female connector and a male connector one being firmly attached to the casing and the other one to the leg, the female connector and the male connector being capable of fitting into each other so as to establish an electric connection from the sole fact of assembling the casing on the leg.

The invention will be better understood from the description which follows, only given as an example and made with reference to the appended drawings, wherein :

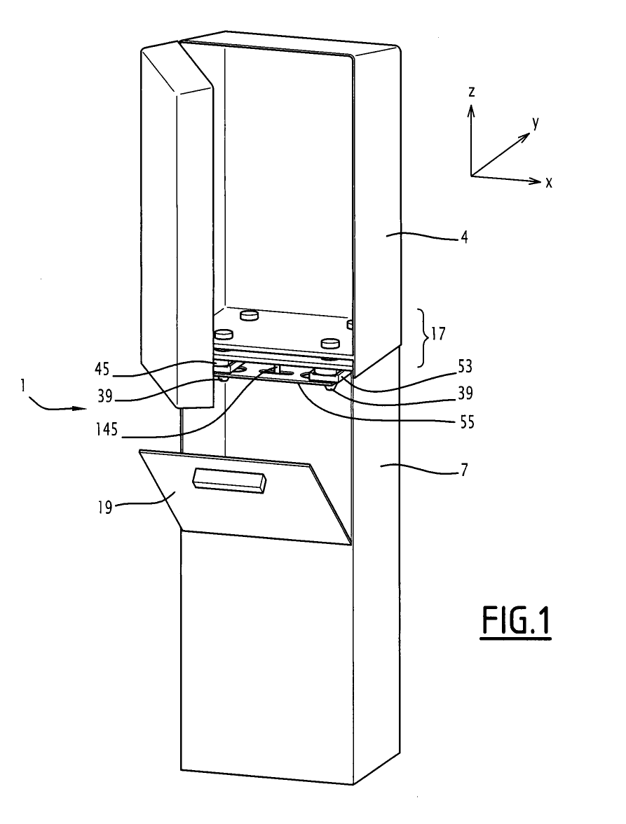

FIG. 1 is an overview of a payment terminal including the assembling device according to the invention;

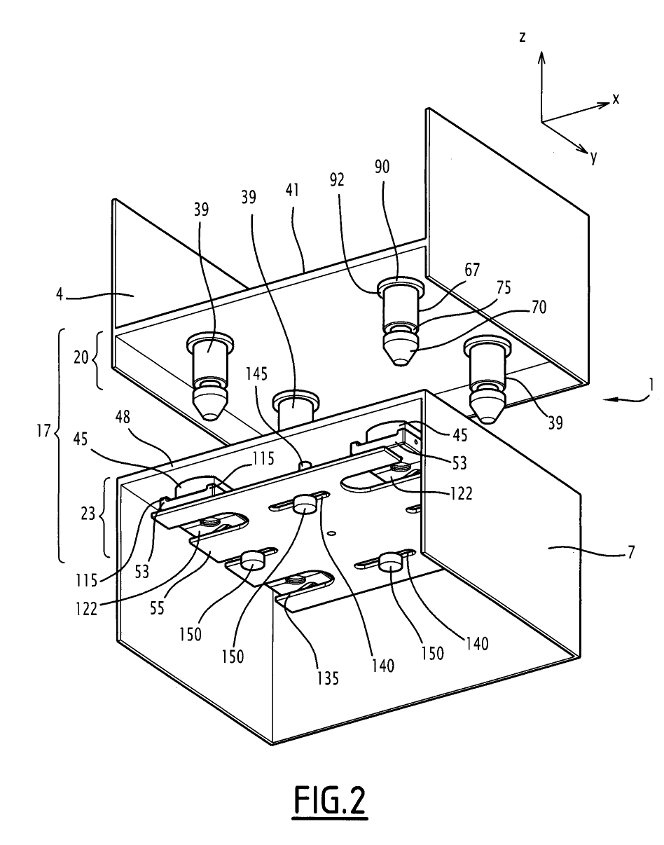

FIG. 2 is an perspective view of the assembling device according to the invention;

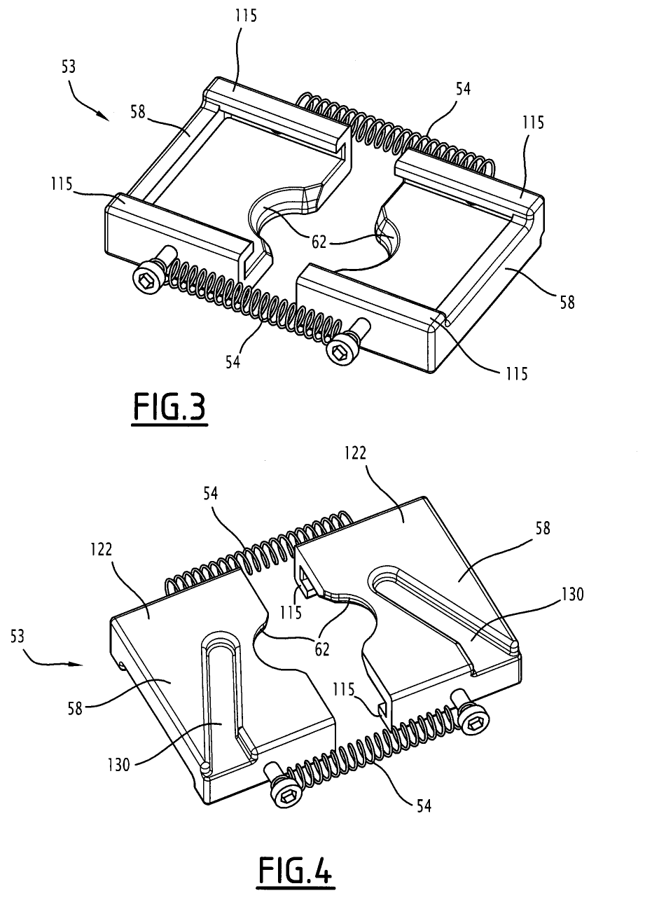

FIG. 3 is a perspective view of the lock according to the invention;

FIG. 4 is a bottom view of the lock according to the invention;

FIG. 5 is a perspective view of the socket and lock according to the invention;

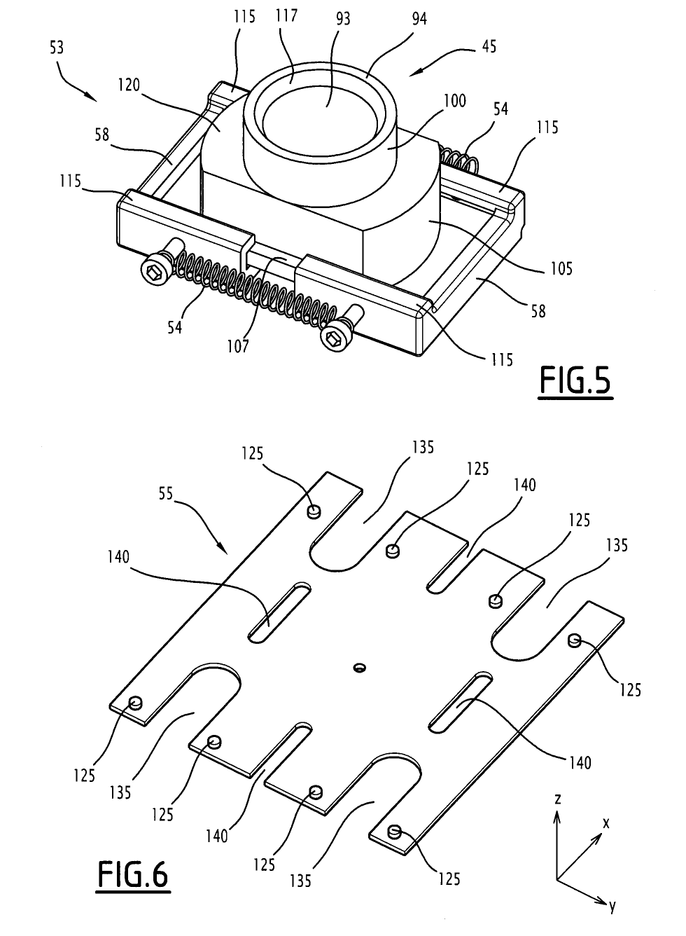

FIG. 6 is a perspective view of the unlocking plate according to the invention; and

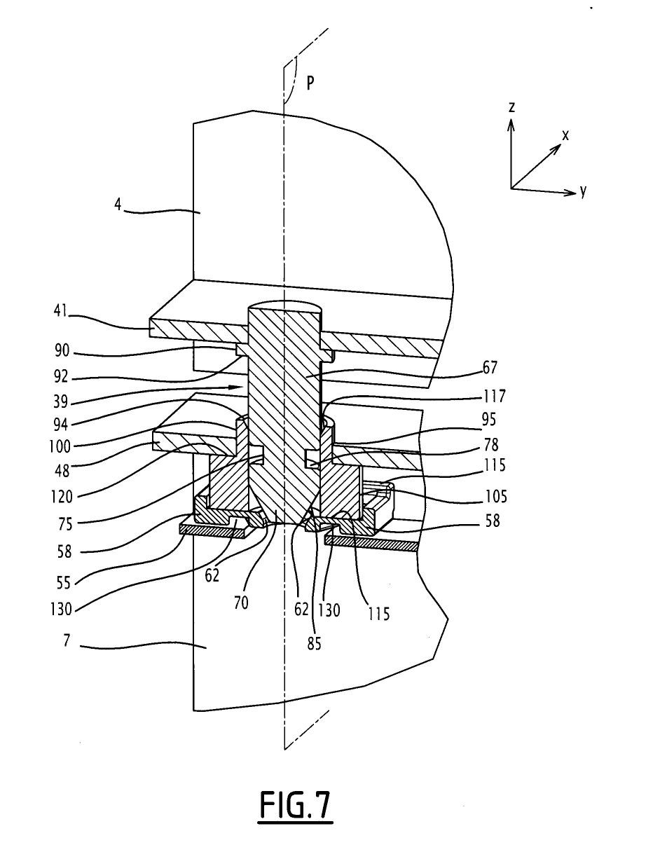

FIGS. 7-10 are sectional views of a portion of the assembling device.

In FIG. 1, a payment terminal 1 is illustrated including a casing 4 containing an electronic payment apparatus, attached on a supporting leg 7 via an assembling device 17. The assembling device 17 comprises elements 20 firmly attached to the casing 4 and elements 23 borne by the leg 7. The leg 7 further includes a collecting hatch 19 giving access to the elements 23.

The casing 4 and the leg 7 respectively provided with the elements 20 and 23 are illustrated in FIG. 2 before their assembling in order to form the payment terminal 1.

The elements 20 of the assembling device 17 include four parallel rods 39, attached on a lower wall 41 of the casing 4, so as to protrude under the lower wall 41.

The elements 23 of the assembling device 17 include four sockets 45 for guiding the rods 39, attached to the upper wall 48 of the leg 7. A lock 53 is provided in the extension of each socket 45 in order to immobilize an associated rod 39. Each lock 53 includes two jaws 58 capable of clasping the associated rod 39 and two springs 54 for returning both jaws 58 towards each other as illustrated in FIG. 3. An unlocking plate 55 sliding relatively to the leg 7 is capable of simultaneously disengaging all the locks 53 from the associated rods 39 on which they are engaged so as to allow disassembling of the payment terminal 1.

Each pair consisting of a socket 45 and of a lock 53 is laid out within the leg 7 so as to be able to co-operate with an associated rod 39 when the casing 4 is positioned on the leg 7.

Each of the four assemblies consisting of a lock 53, of a socket 45 and of an associated rod 39 is identical. Only one of these assemblies will therefore be described subsequently.

Each pair of jaws 58 is symmetrical with respect to the middle plane P of the associated socket 45. The jaws 58 are translationally slidable relatively to the leg 7 and relatively to the socket 45 along a direction perpendicular to the axis of the socket 45 between a set-apart position for releasing the associated rod 39 and a close-together position for retaining the associated rod 39. As shown in FIG. 3, each jaw 58 includes on its side edge located on the side of the other jaw 58 of the pair of jaws 58, a cam-follower surface 62. Each cam-follower surface 62 is a frusto-conical surface extending over 180°. The cam surfaces 62 of each pair of jaws 58 are symmetrical with respect to the middle plane P and move closer to each other in the direction of insertion of the rod 39. The cam surfaces 62 of a pair of jaws 58 delimit between them a space for inserting the associated rod 39.

With reference to FIGS. 2 and 7, the rod 39 includes a cylindrical segment 67 which is extended downwardly by a frusto-conical segment 70. This cylindrical segment 67 includes a radial groove 75 capable of receiving the lock 53. The lower portion of the radial groove 75 forms in the rod 39 a radial shoulder 78, upon which the lock 53 is able to bear when it is engaged on the rod 39. The outer surface of the frusto-conical segment 70 forms a cam surface 85 capable of co-operating with the cam-follower surface 62 of each jaw 58. In the absence of any actuation of the lock 53 by the rod 39, the area of the insertion space delimited by the cam surfaces 62 is smaller than the cross-section of the rod 39 at the radial groove 75.

The cylindrical segment 67 includes, above the radial groove 75, a flange 90, the lower surface of which forms a supporting abutment 92 capable of bearing upon an upper surface 94 of the socket 45.

With reference to FIG. 5, each socket 45 includes an axial through-bore 93 capable of receiving and guiding the associated rod 39. This axial bore 93 opens out on the side of the jaws 58 into the insertion space of the rod 39 formed by the cam-follower surfaces 62 of the jaws 58 of the associated lock 53. The socket 45 is housed in a bore 95 formed in the upper wall 48 of the leg 7. As shown in FIG. 4, it includes an upper cylindrical segment 100, capable of being inserted into the bore 95 and a lower segment 105. The lower segment 105 for example has a rectangular outer cross section. It includes at its low end, two guide rails 107 which extend transversally towards the outside of the socket 45 in a plane substantially parallel to the upper wall 48. The guide rails 107 form a slider into which are engaged the jaws 58. For this purpose, the side edges of the jaws 58 facing the guide rails 107 of the socket 45 each include an edge 115, capable of engaging into the guide rail 107 opposite which it is located. Thus, the rails 107 are capable of guiding the jaws 58 translationally in a direction perpendicular to the axis of the socket 45.

The socket 45 further has, on its upper edge, a cam-follower surface 117, capable of co-operating with the cam surface 85 of the rod 39 in order to center the rod 39 in the socket 45.

The outer cross section of the lower segment 105 is greater than the outer cross section of the upper segment 100. Thus, the upper surface of the lower segment 105 forms a supporting surface 120 for the socket 45 on the lower surface of the upper wall 48 of the leg 7.

The cross-section of the axial bore 93 of the socket 45 corresponds to the maximum outer cross-section of the rod 39. Thus, the socket 45 is capable of receiving and guiding the associated rod 39 when the casing 4 is lowered onto the leg 7.

The distance between the supporting abutment 92 of the flange 90 and the radial shoulder 78 is substantially equal to the distance between the upper surface 94 of the socket 45 and the lower surface 122 of the lock 53. Thus, the rod 39 is capable of bearing upon the upper surface 94 of the socket 45 when the lock 53 is engaged onto the rod 39.

The height of the radial groove 75 is substantially equal to the thickness of the jaws 58.

The unlocking plate 55, illustrated in FIGS. 2 and 6, is laid out under the locks 53. It is translationally displaceable along a direction perpendicular to the displacement direction of the jaws 58 and to the axis of the socket 45 (parallel to the x axis in FIG. 2) between a rest position and an unlocking position. For this purpose it includes slots 140 into which are inserted attachment rods 145.

The attachment rods 145 are attached on the upper wall 48 of the leg 7 at their upper end and provided at their lower end with a cylindrical head 150 with a cross section greater than the cross section of the rod 145. The unlocking plate 55 rests upon the cylindrical heads 150 and is capable of sliding relatively to the rods 145 along a direction perpendicular to the displacement direction of the jaws 58 and perpendicular to the axis of the socket 45 (parallel to the x axis in FIG. 2).

The unlocking plate 55 further comprises four passage orifices 135 capable of letting through the rods 39 when the locks 53 are engaged onto the rods 39. Each passage orifice 135 extends in register with a lock 53.

The unlocking plate 55 includes a pair of unlocking pins 125 for each pair of jaws 58. Each unlocking pin 125 is capable of co-operating with a jaw 58. It protrudes above the unlocking plate 55 and is capable of sliding in a diagonal groove 130 made in the lower surface of the associated jaw 58, illustrated in FIG. 4.

The unlocking pins 125 of a same pair are positioned on either side of an associated orifice 135 symmetrically with respect to the middle plane of this orifice 135. The two diagonal grooves 130 of each pair of jaws 58 are formed so as to converge with the shape of a V towards one of the side edges of the lock 53, including an edge 115. They are symmetrical with respect to the middle plane P of the socket 45.

The fixed distance separating the two unlocking pins 125 of a pair of unlocking pins 125 is substantially equal to the maximum distance between the diagonal grooves 130 of a pair of jaws 58 in its close-together position for retaining the associated rod 39. It is greater than the minimum distance between the diagonal grooves 130 of a pair of jaws 58 in their set-apart position for releasing the associated rod 39.

In the rest position of the unlocking plate 55, the unlocking pins 125 are clear of the associated diagonal grooves 130.

When the unlocking pins 125 are engaged in the associated grooves 130, the unlocking plate 55 is capable by its displacement towards its unlocking position, of causing separation of the jaws 58 of a same pair of jaws 58 by sliding of the unlocking pins 125 in the associated grooves 130 of a pair of jaws 58.

The collecting hatch 19 includes on its inner face, lugs which, when the collecting hatch 19 is closed, protrude towards the inside of the leg 7 at the level of the unlocking plate 55 and are capable of blocking the unlocking plate 55 in its rest position, in which the unlocking pins 125 are clear of the associated diagonal grooves 130.

The leg 7 further includes an extension spring, one of the ends of which is firmly attached to the leg 7 and the other end is firmly attached to the unlocking plate 55. The extension spring is capable of returning the unlocking plate 55 back to its rest position.

The casing 4 and the leg 7 may also respectively include on their facing surfaces a male connector and a female connector capable of fitting into each other in order to establish an electrical connection when the casing 4 is assembled on the leg 7.

FIGS. 7-10 show the operation of the assembling device 17 upon assembling the casing 4 on the leg 7.

During the assembling of the casing 4 on the leg 7, the collecting hatch 19 is closed and the unlocking plate 55 is in its rest position, in which the unlocking pins 125 are clear of the associated diagonal grooves 130.

In order to achieve the assembling of the casing 4 on the leg 7, an operator gradually lowers the casing 4 onto the leg 7 while making sure that each rod 39 is aligned with the associated socket 45. In the case when the initial alignment is not perfect, the cam surface 85 of the rod 39 co-operates with the cam-follower surface 117 of the socket 45 so as to center the rod 39 with respect to the socket 45 and to facilitate its insertion into the socket 45. Once it has penetrated into the socket 45, the rod 39 passes through it with which it is possible to ensure proper positioning of the casing 4 relatively to the leg 7.

In FIG. 7, when the operator continues to lower the casing 4 on the leg 7, the cam surface 85 of the rod 39 comes into contact with the cam-follower surfaces 62 of both jaws 58.

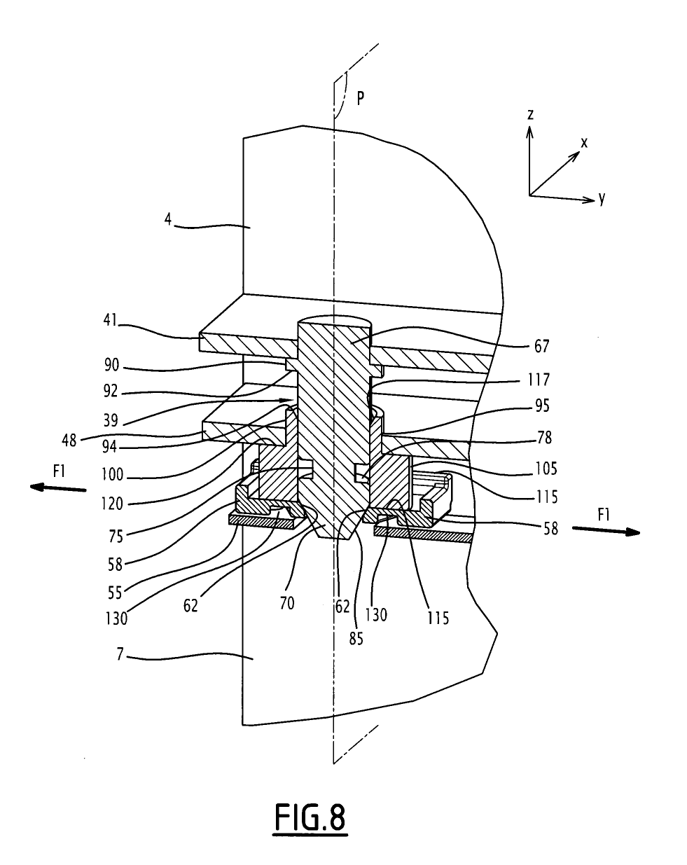

By continuing to lower the casing 4 and therefore to move the rod 39 downwards a moving apart of the jaws 58 of each pair of jaws 58 is then generated, the jaws 58 of each pair of jaws 58 sliding along the guide rails 107 of the socket 45 in the direction of the arrows F1 as illustrated in FIG. 8.

As the rod 39 is gradually driven in, both jaws 58 of each pair of jaws 58 continue to move apart from each other as long as they are in contact with the cam surface 85 of the segment 70.

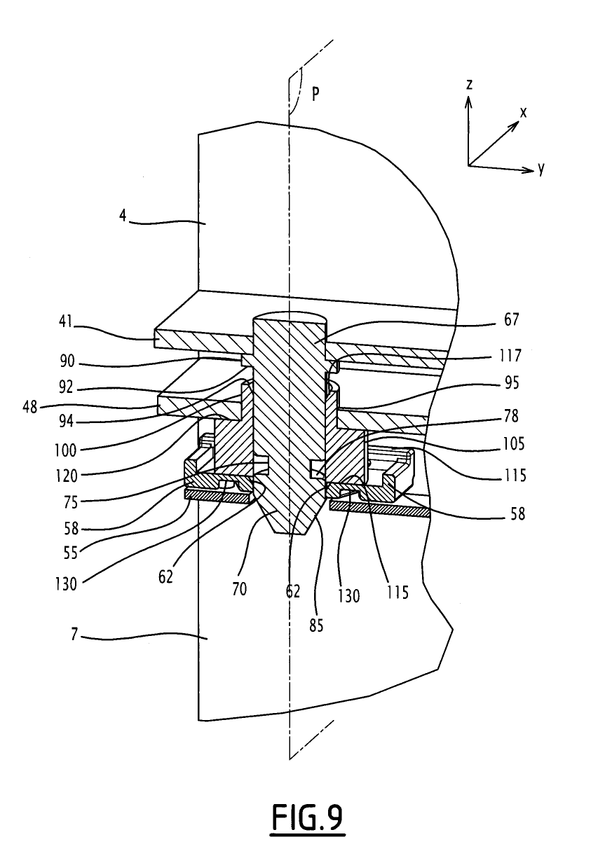

In FIG. 9, the jaws 58 have reached the cylindrical segment 67. This position corresponds to the maximum distance between the jaws 58 of each pair of jaws 58.

Finally, from this position, by continuing to drive in the rod 39, the radial groove 75 is brought opposite to the jaws 58. The return springs 54 connecting the jaws 58 of each lock 53 then bring the jaws 58 back to their close-together position for retaining the associated rod 39. The cam-follower surfaces 62 of the pair of jaws 58 then close onto the segment 67 at the groove 75, the lower surface 122 of the lock 53 bearing upon the shoulder 78.

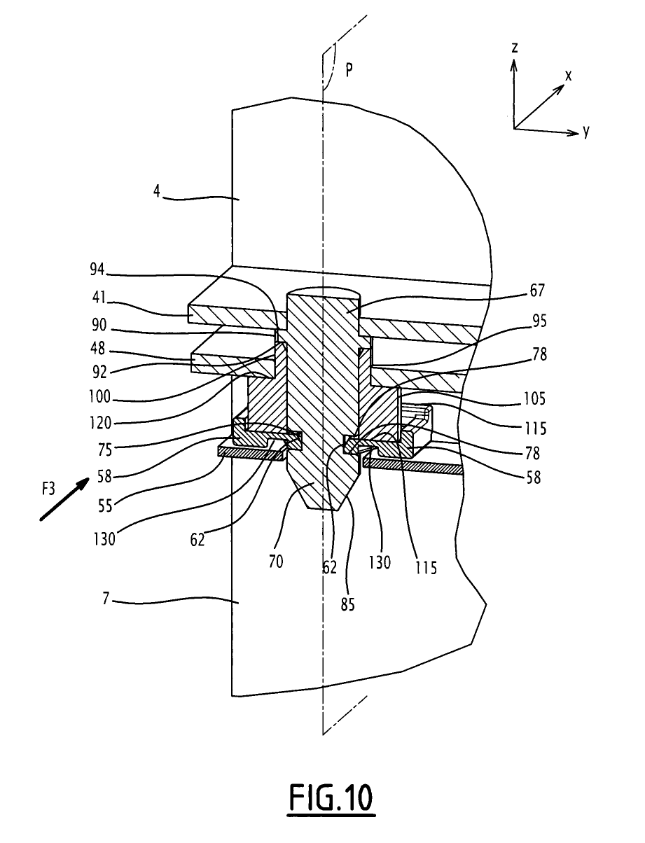

In this position, illustrated in FIG. 10, the lock 53 is engaged onto the rod 39 and the casing 4 is locked on the leg 7. Further, the rod 39 bears upon the upper surface 94 of the socket 45 via the supporting abutment 92 of the flange 90.

In the position illustrated in FIG. 10, the male connector and female connector which are possibly present respectively on the casing 4 and on the leg 7 were fitted into each other in order to establish an electrical contact between the casing 4 and the leg 7 from the sole fact of the casing 4 being assembled with alignment on the leg 7.

When the operator intends to unlock the assembly of the casing 4 on the leg 7 in order to allow disassembling of the payment terminal 1, he/she opens the collecting hatch 19. As the collecting hatch 19 is open, the lugs of the collecting hatch 19 no longer block the displacement of the unlocking plate 55 in the direction of the arrow F3, illustrated in FIG. 10. The operator then pulls on the unlocking plate 55 against the extension spring in order to displace it in the direction of the arrow F3. When the unlocking plate 55 has been sufficiently translated in the direction of the arrow F3, the unlocking pins 125 engage into the diagonal grooves 130 of the associated jaws 58. As the distance between the unlocking pins 125 is fixed, continuation of this translation induces the simultaneous moving apart of the jaws 58 of each pair of jaws 58 in the direction of the arrows F1 of FIG. 8.

When the unlocking plate 55 reaches its unlocking position, in which the jaws 58 are in their set-apart position for releasing the associated rod 39, which allows disengagement of the rod 39, the unlocking plate 55 is maintained in this position by any suitable means. The operator may then disengage the rods 39 from the locks 53 by lifting the casing 4 relatively to the leg 7 and thereby disassemble the casing 4 from the leg 7.

According to alternatives of the present invention, the assembling device 17 comprises a number of rods 39, sockets 45 and locks 53 which is different from 4 and greater than or equal to 1.

According to another alternative of the present invention, the elements 20 of the assembling device 17 are borne by the leg 7 and the elements 23 are attached to the casing 4.

The assembling device according to the invention has the advantage of allowing automatic locking of the casing on the leg, from the sole fact of the lowering of the casing on the leg by the operator, without using particular tools and without it being necessary that the operator accesses the inside of one of these two elements and possibly removes certain elements contained in the casing in order to access the assembling device. Further, as the pairs of jaws are independent of each other, it provides locking in four independent points. This property increases the protection of the payment terminal against vandalism, since in order to manage to dissociate the casing from the leg, a possible vandal has to successively attack the four locking points.

The blocking of the displacement of the unlocking plate in the direction for moving the jaws apart when the collecting hatch is closed also makes the assembling device more secure. Indeed, only authorized persons have the possibility of opening the collecting hatch. They alone may therefore access the simultaneous unlocking mechanism of the locks.

Moreover the assembling device provides a significant gain in time upon assembling the payment terminal, since the operator has nothing more to do than lower the casing on the leg in order to achieve locking of the assembly.

Finally, the absence in the assembling device of attachment parts likely to deteriorate during the lifetime of the payment terminal, under the effect of external conditions is also advantageous. Indeed in known devices, the attachment elements such as the threaded rods corrode during the lifetime of the payment terminal, which makes its disassembling difficult.

Disassembly is facilitated by the structure of the unlocking plate which allows simultaneous unlocking of all the locks, which generates a gain in time.

The invention generally applies to payment terminals intended to be set up on public roads, such as parking meters.

1. A payment terminal including a casing (4) containing an electronic payment apparatus, a supporting leg (7) for supporting the casing (4) and an assembling device (17) for assembling the casing (4) on the leg (7), which assembling device (17) includes a rod (39) firmly attached to a first module among the casing (4) and the leg (7) and a lock (53) borne by a second module among the casing (4) and the leg (7) and able to co-operate with the rod (39) for assembling the casing (4) and the leg (7), characterized in that the assembling device (17) further includes elastic engagement means (54) for elastically engaging the lock (53) on the rod (39).

2. The payment terminal according to claim 1, characterized in that the rod (39) includes a cam surface (85) capable of co-operating with a cam-follower surface (62) of the lock (53) so as to cause stretching of the elastic engagement means (54).

3. The payment terminal according to claim 2, characterized in that the lock (53) includes two jaws (58) delimiting between them the cam-follower surface (62) and capable of sliding in opposite directions under the action of the rod (39).

4. The payment terminal according to claim 3, characterized in that the elastic engagement means include two springs (54), capable of returning the jaws (58) towards each other so as to engage the lock (53) on the rod (39).

5. The payment terminal according to any one of claims 2 to 4, characterized in that the rod (39) includes a cylindrical segment (67) and a frusto-conical segment (70) forming said cam surface (85) and the cross-section of which gradually decreases upon moving away from the cylindrical segment (67).

6. The payment terminal according to any of the preceding claims, characterized in that the second module further includes a socket (45) for guiding the rod (39).

7. The payment terminal according to claim 6, characterized in that the guide socket (45) includes guide rails (107) capable of guiding the lock (53) translationally.

8. The payment terminal according to any of the preceding claims, characterized in that the rod (39) includes a radial shoulder (78) on which the lock (53) is capable of being supported upon its engagement onto the rod (39).

9. The payment terminal according to claim 8 taken in combination with claims 5 and 6 or according to claim 8 taken in combination with claims 5 and 7, characterized in that the guide socket (45) includes an upper surface (94), the lock (53) includes a lower surface (122) and in that the rod (39) includes, in the cylindrical segment (67), a flange (90) forming a supporting abutment (92) capable of bearing upon the upper surface (94), the distance between the supporting abutment (92) and the radial shoulder (78) being substantially equal to the distance between the upper surface (94) of the guide socket (45) and the lower surface (122) of the lock (53).

10. The payment terminal according to any of the preceding claims, characterized in that the assembling device (17) includes at least two rods (39), firmly attached to the first module among the casing (4) and the leg (7) and at least the two locks (53) borne by the second module among the casing (4) and the leg (7) and each able to co-operate with an associated rod (39) for assembling the casing (4) and the leg (7) and elastic engagement means (54) for elastically engaging each lock (53) onto the associated rod (39).

11. The payment terminal according to claim 10, characterized in that the second module further comprises an unlocking plate (55) capable of simultaneously disengaging all the locks (53) from the associated rods (39).

12. The payment terminal according to claim 11 in combination with claim 3, characterized in that the unlocking plate (55) is capable of sliding relatively to the second module in a direction normal to the sliding direction of the jaws (58) so as to generate a moving-apart of the jaws (58) of each lock (53).

13. The payment terminal according to claim 12, characterized in that the second module includes a collecting hatch (19) capable of blocking the sliding of the unlocking plate (55) when the collecting hatch (19) is closed.

14. The payment terminal according to any of the preceding claims, characterized in that it further includes a female connector and a male connector, one firmly attached to the casing (4) and the other one firmly attached to the leg (7), the female connector and the male connector being capable of fitting into each other so as to establish an electrical connection from the sole fact of the assembling of the casing (4) on the leg (7).
